(19) United States
(12) Patent Application Publication
(10) Pub. No.: US 2025/0354258 A1
(43) Pub. Date: Nov. 20, 2025

(54) DRY CLEAN MODULE FOR CLEANING GAS DISTRIBUTION PLATES

(71) Applicant: Applied Materials, Inc., Santa Clara, CA (US)

(72) Inventors: Duh-yang HSU, Tainan City (TW); Stacy J. MEYER, San Jose, CA (US); Shih-chang CHEN, Tainan City (TW); Chia-yu CHANG, Taichung (TW); Minghao LI, Santa Clara, CA (US); Hsing Szu CHEN, Kaohsiung (TW); Shao-Chiang Philip SHIH, Taichung (TW); Chia-pin LIN, Tainan City (TW); Han-Pin HUANG, Taichung (TW)

(21) Appl. No.: 19/197,515

(22) Filed: May 2, 2025

Related U.S. Application Data
(60) Provisional application No. 63/647,574, filed on May 14, 2024.

(51) Int. Cl. C23C 16/44; B08B 3/12; C23C 16/52; H01J 37/32

(52) U.S. Cl. CPC C23C 16/4405; B08B 3/12; C23C 16/52; H01J 37/32862; H01J 2237/335

(57) ABSTRACT

Embodiments of the present disclosure generally relate to a method of dry cleaning a gas distribution plate for a plasma processing system. The method begins by exposing one or more of the gas passages in the gas distribution plate to a dry cleaning tool. Ultrasonic waves are directed from the nozzle at the deposited film in the gas passages. The film particles comprised of a lower density portion of the deposited film are removed away from the gas distribution plate by the dry cleaning tool. The method continues by indexing the nozzle of the dry cleaning tool across the gas distribution plate.

### CROSS-REFERENCE TO RELATED APPLICATIONS

This application claims benefit of U.S. Provisional Application Ser. No. 63/647,574, filed May 14, 2024 (Attorney Docket No. APPM/44023685US01), of which is incorporated by reference in its entirety.

### BACKGROUND

### Field

Embodiments of the present disclosure generally relate to a method of cleaning a gas distribution plate in a chemical vapor deposition processing systems.

### Description of the Background Art

Liquid crystal displays or flat panels are commonly used for active matrix displays such as computer and television monitors. Both chemical vapor deposition (CVD) and plasma enhanced chemical vapor deposition (PECVD) are generally employed to deposit thin films on a substrate such as a transparent glass substrate (for flat panel) or semiconductor wafer. CVD is generally accomplished by introducing a precursor gas or gas mixture into a vacuum chamber that contains a flat panel. The precursor gas or gas mixture is typically directed downwardly through a distribution plate situated near the top of the chamber. The precursor gas or gas mixture in the chamber is energized (e.g., excited) into a plasma by applying radio frequency (RF) power to the chamber from one or more RF sources coupled to the chamber. The excited gas or gas mixture reacts to form a layer of material on a surface of the flat panel that is positioned on a temperature controlled substrate support. Volatile by-products produced during the reaction are pumped from the chamber through an exhaust system.

Flat panels processed by PECVD or CVD techniques are typically large, often exceeding 370 mm×470 mm and ranging over 5.5 square meters (m²) in size. For example, next generation G10.5 substrates are about 3,000 mm×3,400 mm and define sizes as large as 10.0 m². Diffuser plates, or gas distribution plates, are utilized to provide uniform process gas flow over the flat panels. The gas distribution plate are relatively large in size, particularly as compared to gas distribution plates utilized for 200 mm and 300 mm semiconductor wafer processing.

During deposition in flat panel processing, deposition material starts to build up in the individual gas flow holes of the distribution plate. Eventually, the distribution plate will require the individual gas flow holes to be cleaned of deposited material in order to maintain the requisite flow of gas evenly distributed across the distribution plate. As the number of gas flow holes formed through the gas distribution plate is proportional to the size of the flat panel, the great number of holes formed in each plate disadvantageously contributes to a length of down time needed for chemical cleaning of the gas distribution plate. A typical chemical cleaning process requires the removal of a backing plate from the gas distribution plate and sending the gas distribution plate to a third party cleaning house for chemical cleaning. However, conventional chemical cleaning processes often enlarges the size of the gas flow holes, resulting in the distribution of gases flowing out of the gas distribution plate being out of specified and designed parameters. Thus, each cleaning of the gas distribution plate shortens the useful life span of the gas distribution plate, ultimately resulting in the need to replace the gas distribution plate and increasing the overall cost of operating the processing equipment.

Therefore, there is a need for an improved method of cleaning distribution plates.

### SUMMARY

Embodiments of the present disclosure generally relate to a method of dry cleaning a gas distribution plate for a plasma processing system. The method begins by exposing one or more of the gas passages in the gas distribution plate to a dry cleaning tool. Ultrasonic waves are directed from the nozzle at the deposited film in the gas passages. The film particles comprised of a lower density portion of the deposited film are removed away from the gas distribution plate by the dry cleaning tool. The method continues by indexing the nozzle of the dry cleaning tool across the gas distribution plate.

### BRIEF DESCRIPTION OF THE DRAWINGS

So that the way the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic cross-sectional view of an illustrative processing chamber having one embodiment of a gas distribution plate according to embodiments described herein.

FIG. 2 depicts a cross-sectional schematic view of an embodiment of a gas distribution plate according to embodiments described herein.

FIGS. 3A-3B depict portions of the gas distribution plate where deposited film accumulates.

FIG. 4 depicts a schematic view of a dry cleaning tool for cleaning a gas hole in the gas distribution plate according to embodiments described herein.

FIGS. 5A-5D depict side schematic views of a gas distribution plate illustrating various amounts of deposited film disposed on the gas distribution plate.

FIG. 6 shows a process flow for removing deposited film from gas holes of the gas distribution plate according to embodiments described herein.

FIG. 7 shows a process flow for dry cleaning the distribution plate suitable for use with the process flow disclosed in FIG. 6.

To facilitate understanding, identical reference numerals have been used, where possible, to designate identical elements that are common to the figures.

### DETAILED DESCRIPTION

The disclosure is illustratively described below in reference to a chemical vapor deposition system configured to process large area substrates, such as a plasma enhanced chemical vapor deposition (PECVD) system, available from AKT, a division of Applied Materials, Inc., Santa Clara, California. However, it should be understood that the subject matter has utility in other system configurations such as etch systems, other chemical vapor deposition systems and any other system in which distributing gas within a process chamber is desired, including those systems configured to process round substrates. The diffusion plate is sized and configured for the deposition of doped or un-doped (intrinsic) amorphous silicon (α-Si), silicon dioxide (SiO2), silicon oxynitride (SiON) and silicon nitride (SiN) films used in liquid crystal displays (or flat panels). The disclosure generally provides a method of cleaning the gas distribution plate of the deposited material which undesirably accumulates in the gas holes of the diffusion plate. The cleaning method disclosed below extends the useful life span of the gas distribution plate beyond conventional chemical cleaning methods.

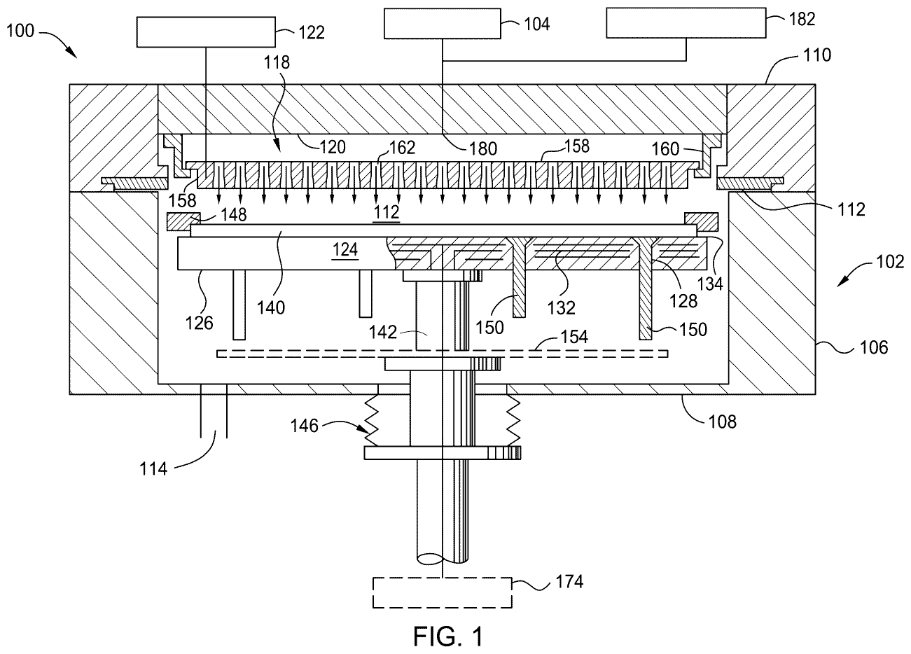

FIG. 1 is a schematic cross-sectional view of one embodiment of a chemical vapor deposition (CVD) system 100, available from AKT, a division of Applied Materials, Inc., Santa Clara, California. The (CVD) system 100 generally includes a processing chamber body 102 coupled to a gas source 104. The processing chamber body 102 has walls 106 and a bottom 108 that partially define a process volume 112. The process volume 112 is typically accessed through a port (not shown) in the walls 106 that facilitate movement of a substrate 140 into and out of the processing chamber body 102. The walls 106 and bottom 108 are typically fabricated from a unitary block of aluminum or other material compatible with processing. The walls 106 support a lid assembly 110. A pumping port 114 is disposed through the bottom 108 and couples the process volume 112 to an exhaust port (that includes various pumping components, not shown).

A temperature controlled support assembly 138 is centrally disposed within the processing chamber body 102. The support assembly 138 supports the substrate 140 during processing. In one embodiment, the support assembly 138 comprises an aluminum body 124 that encapsulates at least one embedded heater 132. The heater 132, such as a resistive element, disposed in the support assembly 138, is coupled to an optional power source 174 and controllably heats the support assembly 138 and the substrate 140 positioned thereon to a predetermined temperature. Typically, in a CVD process, the heater 132 maintains the substrate 140 at a uniform temperature exceeding about 150 or more degrees Celsius, depending on the deposition processing parameters for the material being deposited.

Generally, the support assembly 138 has a lower side 126 and an upper side 134. The upper side 134 supports the substrate 140. The lower side 126 has a stem 142 coupled thereto. The stem 142 couples the support assembly 138 to a lift system (not shown) that moves the support assembly 138 between an elevated processing position (as shown) and a lowered position that facilitates substrate transfer to and from the processing chamber body 102. The stem 142 additionally provides a conduit for electrical and thermocouple leads between the support assembly 138 and other components of the CVD system 100.

A bellows 146 is coupled between support assembly 138 (or the stem 142) and the bottom 108 of the processing chamber body 102. The bellows 146 provides a vacuum seal between the process volume 112 and the atmosphere outside the processing chamber body 102 while facilitating vertical movement of the support assembly 138.

The support assembly 138 additionally supports a circumscribing shadow frame 148. Generally, the shadow frame 148 prevents deposition at the edge of the substrate 140 and support assembly 138 so that the substrate does not stick to the support assembly 138. The support assembly 138 has a plurality of holes 128 disposed therethrough that accept a plurality of lift pins 150. The lift pins 150 are typically comprised of ceramic or anodized aluminum. The lift pins 150 may be actuated relative to the support assembly 138 by an optional lift plate 154. The optional lift plate 154 moves the lift pins 150 between a position flush with the support surface 130 to elevated above the support surface. Thereby the lift pins 150 place the substrate 140 in a spaced-apart relation to the support assembly 138 for transfer through the port (not shown) in the walls 106 that facilitate movement of a substrate 140 into and out of the processing chamber body 102.

The lid assembly 110 provides an upper boundary to the process volume 112. The lid assembly 110 typically can be removed or opened to service the processing chamber body 102. In one embodiment, the lid assembly 110 is fabricated from aluminum (Al). The lid assembly 110 typically includes an entry port 180 through which process gases provided by the gas source 104 is introduced into the processing chamber body 102. The entry port 180 may also be coupled to a cleaning source 182. The cleaning source 182 typically provides a cleaning agent, such as disassociated fluorine, that is introduced into the processing chamber body 102 to remove deposition by-products and films from processing chamber hardware, including the showerhead assembly 118.

The support assembly 138 generally is grounded such that RF power supplied by a power source 122 to a showerhead assembly 118 positioned between the lid assembly 110 and support assembly 138 (or other electrode positioned within or near the lid assembly of the chamber) may excite gases present in the process volume 212 between the support assembly 138 and the distribution plate 118. The RF power from the power source 222 is generally selected commensurate with the size of the substrate to drive the chemical vapor deposition process.

The showerhead assembly 118 is coupled to an interior side 120 of the lid assembly 110. The showerhead assembly 118 is typically configured to substantially follow the profile of the substrate 140, for example, polygonal for large area flat panel substrates and circular for wafers. The showerhead assembly 118 includes a perforated area 116 through which process and other gases supplied from the gas source 104 are delivered to the process volume 112. The perforated area 116 of the showerhead assembly 118 is configured to provide uniform distribution of gases passing through the showerhead assembly 118 into the processing chamber body 102.

The showerhead assembly 118 typically includes a distribution plate 158, i.e., a gas distribution plate, suspended from a hanger plate 160. The gas distribution plate 158 and hanger plate 160 may alternatively comprise a single unitary member. A plurality of gas passages 162 are formed through the gas distribution plate 158 to allow a predetermined distribution of gas passing through the showerhead assembly 118 and into the process volume 112. The hanger plate 160 maintains the gas distribution plate 158 and the interior surface 120 of the lid assembly 110 in a spaced-apart relation, thus defining a plenum 164 between the interior surface 120 and the distribution plater 150. The plenum 164 allows gases flowing through the lid assembly 110 to uniformly distribute across the width of the gas distribution plate 158 so that gas is provided uniformly above the center of the gas distribution plate 158 and flows with a uniform distribution through the gas passages 162.

The gas distribution plate 158 is typically fabricated from stainless steel, aluminum (Al), anodized aluminum, nickel (Ni) or other RF conductive material. The gas distribution plate 158 is configured with a thickness that maintains sufficient flatness across the process volume 112 as not to adversely affect processing the substrate 140. In one embodiment the gas distribution plate 158 has a thickness between about 1.0 inch to about 2.0 inches. The gas distribution plate 158 could be circular for semiconductor wafer manufacturing or polygonal, such as rectangular, for flat panel display manufacturing. In one example of a distribution plate for flat panel display application, the gas distribution plate 158 is a rectangle.

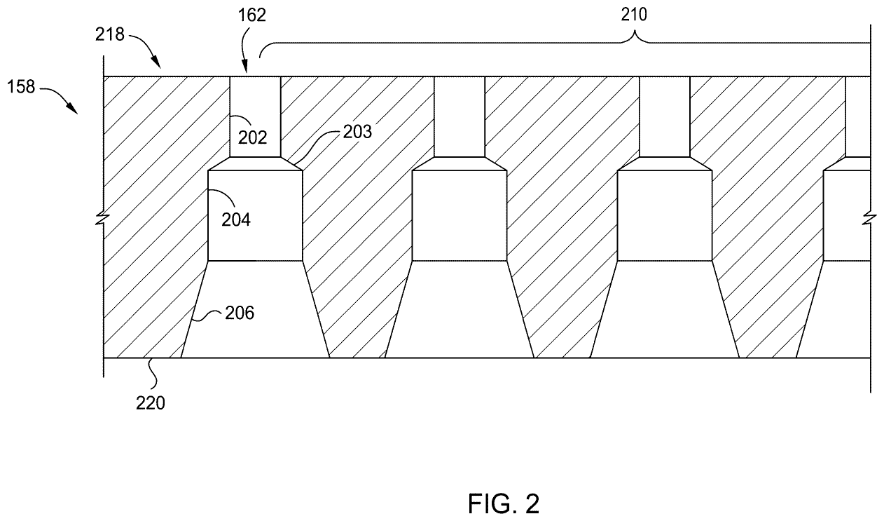

FIG. 2 is a partial sectional view of the gas distribution plate 158 that is described above. For example, for a 1080 in² (e.g. 30 inches×36 inches) distribution plate, the gas distribution plate 158 includes about 16,000 gas passages 162. For larger distribution plates used to process larger flat panels, the number of gas passages 162 could be as high as 100,000. The gas passages 162 are generally patterned to promote uniform deposition of material on the substrate 140 positioned below the gas distribution plate 158. In one embodiment, the gas passage 162 is comprised of a restrictive section 202, a flared connector 203, a center passage 204 and a flared opening 206. The restrictive section 202 passes from the first side 218 of the gas distribution plate 158 and is coupled to the center passage 204. The center passage 204 has a larger diameter than the restrictive section 202. The restrictive section 202 has a diameter selected to allow prescribed amount of gas flow through the diffusion plate 158 while providing enough flow resistance to ensure uniform gas distribution radially across the perforated center portion 210. For example, the diameter of the restrictive section 202 could be about 0.016 inch. The flared connector 203 connects the restrictive section 202 to the center passage 204. The flared opening 206 is coupled to the center passage 204 and has a diameter that tapers radially outwards from the center passage 204 to a second side 220 of the gas distribution plate 158. The flared openings 206 promote plasma ionization of process gases flowing into the process volume 112. Moreover, the flared openings 306 provide larger surface area for hollow cathode effect to enhance plasma discharge.

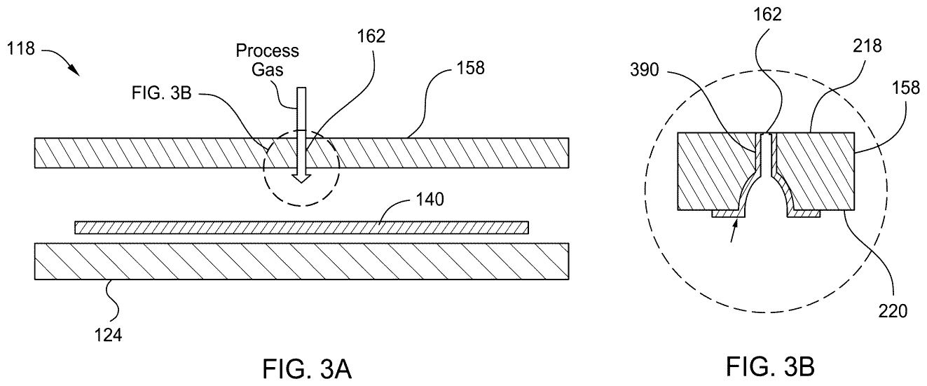

The gas distribution plate 158 utilized for flat panel processing have large number of gas passages 162 through which process gases pass and which start to accumulate film build up from the deposition process. FIGS. 3A-3B depict portions of the gas distribution plate where deposited film typically accumulates.

FIG. 3A is a pictorial simplification of the deposition process gas flowing through the gas passage 162 in the gas diffusion plate 158. The deposition gas flows through the entry port 180 (shown in FIG. 1) and is disassociated to create a film layer on the substrate 140. The deposition gas may be ionized by a plasma process for creating the layer of material deposited on the substrate 140.

The material from the deposition gas additionally adheres and forms films in locations other than the substrate 140 within to the processing chamber 100. For example, material from the deposition gas may form a deposited film 390 on the distribution plate 158 as shown in FIG. 3B. The deposited film 390 may cover the second side 220 as well as the gas passages 162. Additionally as shown in FIG. 3B, the deposited film 390 chokes the gas passage 162 as the deposited film 390 builds up within the gas passages 162 of the gas distribution plate 158. Without removal, the deposited film 390 would eventually restrict the process gas flow through one or more of the gas passages 162 formed through the gas diffusion plate 158, thus preventing uniform film deposition on the substrate 140. Therefore, the deposited film 390 may be cleaned from the diffusion plate 158 at regular intervals in order to maintain the required gas flow through the gas passages 162 and acceptable film deposition results.

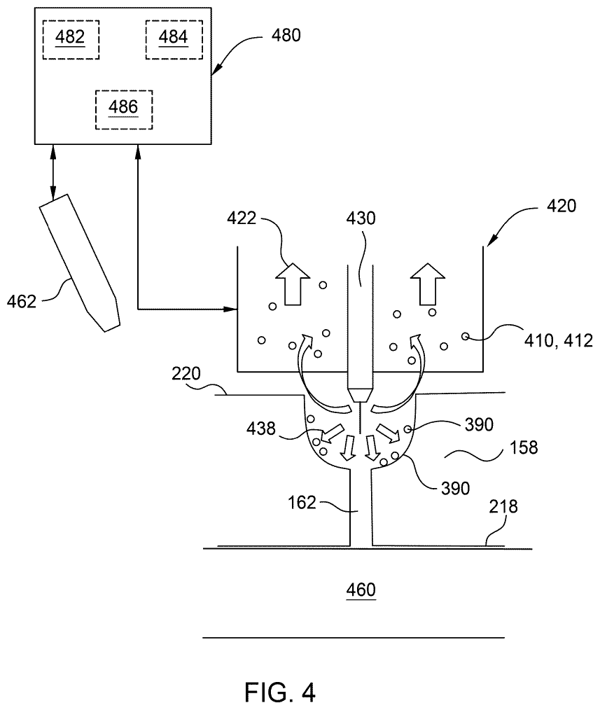

FIG. 4 depicts a schematic view of a dry cleaning tool for cleaning a gas passages 162 in the gas distribution plate 158 according to embodiments described herein. The gas distribution plate 158 may be placed on a table or jig to align the gas passages 162 with a dry cleaning tool 420. For example, the table may be moveable in an x/y direction for aligning the gas passages 162 with the dry cleaning tool 420. Alternately, the dry cleaning tool 420 may be moveable in an x/y direction for aligning with the gas passages 162. A sensor 462 may be disposed on the dry cleaning tool 420 for determining the location of the gas passages 162. In one example, the sensor 462 is a camera. The sensor 462 provides a map of all the gas passages to proper align the dry cleaning tool 420 with the gas passages 162. In this manner, each gas passage 162 may be geographically located or known by the dry cleaning tool 420 to ensure all the gas passages 162 are cleaned.

The dry cleaning tool 420 has an ultrasonic nozzle 430 which is used in a dry environment to dislodge the film particles 412 from the deposited film 390 for removal by the dry cleaning tool 420. For example, the ultrasonic nozzle 430 uses ultrasonic waves without a liquid medium to remove the deposited film 390.

A system controller 480 is coupled to the dry cleaning tool 420 for controlling the dry cleaning tool 420 or components thereof. For example, the system controller 480 may be in communication with the sensor 462 and control the operations of the dry cleaning tool 420 using a direct control of the ultrasonic nozzle 430 of the dry cleaning tool 420 by controlling the table 460 associated with the dry cleaning tool 420. In operation, the system controller 480 enables the dry cleaning tool 420 to dry clean each gas passage 162 in the gas distribution plate 158 as discussed in the process flow 700.

The system controller 480 generally includes a central processing unit (CPU) 482, memory 484, and support circuits 486. The CPU 482 may be one of any form of a general purpose processor that can be used in an industrial setting. The memory 484, non-transitory computer-readable medium, or machine-readable storage device, is accessible by the CPU 482 and may be one or more of memory such as random access memory (RAM), read only memory (ROM), floppy disk, hard disk, or any other form of digital storage, local or remote. The support circuits 486 are coupled to the CPU 482 and may comprise cache, clock circuits, input/output subsystems, power supplies, and the like. The system controller 480 is configured to perform the process flow 700 stored in the memory 484. The various implementations disclosed in this disclosure may generally be implemented under the control of the CPU 482 by executing computer instruction code stored in the memory 484 (or in memory of a particular process chamber) as, e.g., a computer program product or software routine. That is, the computer program product is tangibly embodied on the memory 484 (or non-transitory computer-readable medium or machine-readable storage device). When the computer instruction code is executed by the CPU 482, the CPU 482 controls the dry cleaning tool 420 and/or table 460 to perform operations of process flows 600, 770 described below in accordance with the various implementations.

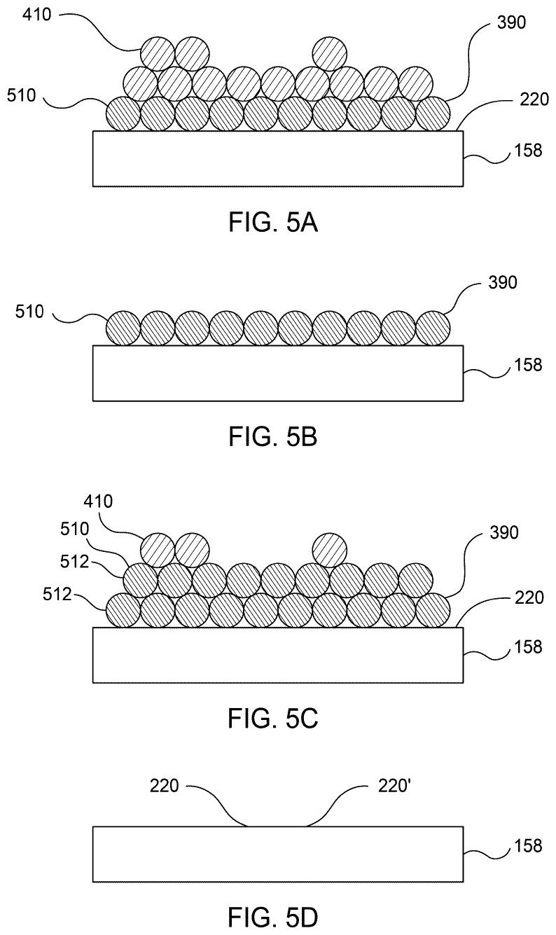

FIGS. 5A-5D depict partial side schematic views of the gas distribution plate 158 illustrating various amounts of deposited film 390 disposed on the gas distribution plate 158. The deposited film 390, i.e., the residual deposits, is shown on the second side 220 of the gas distribution plate 158. However it should be understood, that the deposited film 390 is additionally present throughout the gas passages 162 and in particular in the restrictive section 202 and flared openings 206.

As shown in FIG. 5A, the deposited film 390 eventually accumulates to a depth in which the restrictive section 202 is reduced in the interior diameter. The reduced interior diameter of the restrictive section 202 results in a reduced gas flow through the gas distribution plate 158. The deposited film 390 is denser at or near the second side 220 of the gas distribution plate 158. For example, the deposited film 390 may be comprised of a high density portion 510 adjacent the second side 220 of the distribution plate. A lower density portion 410 may be disposed on top of the high density portion 510. The lower density portion 410 is that portion of the deposited film 390 which last accumulated.

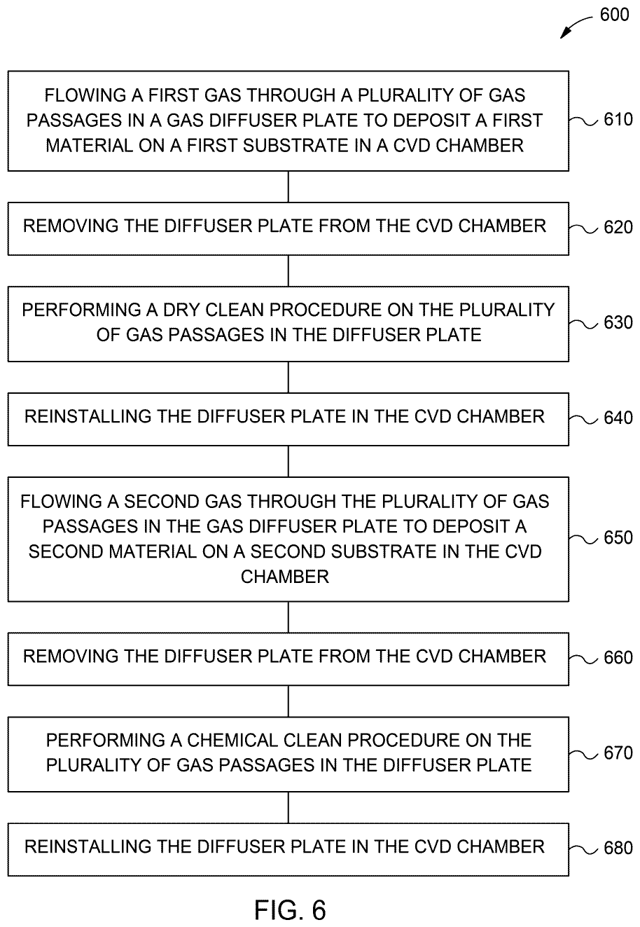

FIG. 6 illustrates a process flow 600 for removing deposited film from gas passages of a gas distribution plate, according to embodiments described herein. Process flow 600 will be discussed with the aid of FIG. 4 and FIGS. 5A-5B.

The process flow 600 begins at operation 610 by flowing a first gas through a plurality of gas passages in a gas distribution plate to deposit a first material on a first substrate in a CVD chamber. Operation 610 may be repeated for several batches of substrates where material is deposited by the CVD chamber 1000 in accordance with a recipe to build devices on the substrates. During deposition, the first gas may additionally form residual deposits on the gas distribution plate 158. The residual deposits may build up over several deposition processes and begin to clog or obstruct the gas passages 162 formed in the gas distribution plate 158.

The process flow 600 continues at operation 620 by removing the gas distribution plate 158 from the CVD chamber. The CVD chamber is taken offline for maintenance of the gas distribution plate 158 in operation 620. The CVD chamber remains idle and no further deposition operations may be performed on substrates while the chamber is offline for maintenance. The gas distribution plate 158 may be removed from the showerhead assembly 118. In one embodiment, the gas distribution plate 158 is moved to a cleaning facility to remove all or portions of the deposited film 390.

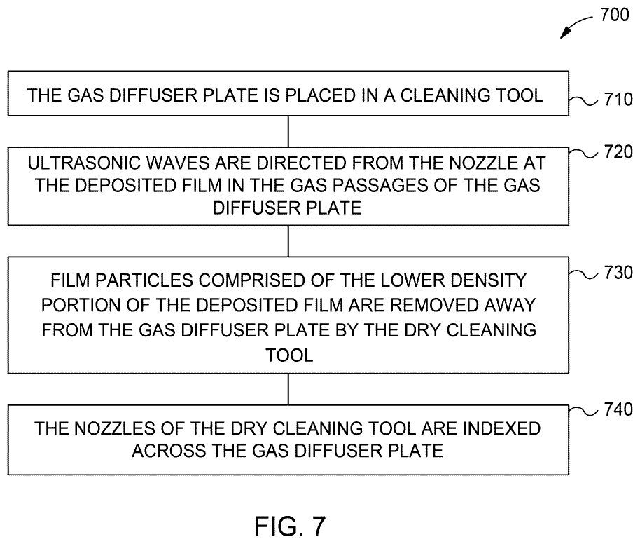

At operation 630, a dry clean procedure is performed on the plurality of gas passages in the distribution plate. FIG. 7 shows a process flow 700 for dry cleaning the distribution plate suitable for use with the process flow disclosed in FIG. 6. At the beginning of operation 630, the deposited film 390 is disposed on the gas distribution plate 158. The deposited film 390 includes both the high density portion 510 and the lower density portion 410 of the deposited film 390.

Process flow 700 begins at operation 710 where one or more of the gas passages 162 in the gas distribution plate 158 are exposed to a dry cleaning tool 420. The gas distribution plate 158 may be placed on the table 460 or jig to align the gas passages 162 with one or more ultrasonic nozzles 430 of the dry cleaning tool 420. The dry cleaning tool may extend over a single gas passage 162. Alternately, the dry cleaning tool 420 may extend over several gas passages 162. For example, the dry cleaning tool 420 has four or more ultrasonic nozzles 430 which align with four or more gas passages 162. In this manner, the four or more nozzles 430 simultaneously clean the four or more gas passages 162 of the gas distribution plate 152.

In one example, the dry cleaning tool 420 is moveably coupled to the table 460 or jig. The gas distribution plate 158 is positionally located on the table 460 or jig. The gas passages 162 of the gas distribution plate 158 may be mapped for further reference by the dry cleaning tool 420. In this manner, the position of the dry cleaning tool 420 with respect to the gas passages 162 can be known. In one example, a recipe may be established for indexing the dry cleaning tool 420 along the gas distribution plate 158 to address and clean each gas passage 162. In another example, the dry cleaning tool 420 is not coupled to the table 460 or jig and moves independently from the table 460 across the gas distribution plate 158. In this example, the dry cleaning tool 420 may receive instructions and be moved by the controller 480. Alternately, the dry cleaning tool 420 may be manually moved across the gas distribution plate 158.

At operation 720, ultrasonic waves are directed from the ultrasonic nozzle 430 at the deposited film 390 in the gas passages 162. The ultrasonic waves 438 dislodge the lower density portion 410 of the deposited film 390 from the gas passages 162. The lower density portion 410 of the deposited film 390 is released from the deposited film 390 as film particles 412.

At operation 730, film particles 412 comprised of the lower density portion 410 of the deposited film 390 are removed away from the gas distribution plate 158 by the dry cleaning tool 420. The dislodged lower density portion 410 of the deposited film 390 are pulled into a vacuum orifice 422 by a vacuum or other techniques for attracting the film particles 412. The film particles 412 may be collected in a hopper or other containing device for disposal.

At operation 740, the ultrasonic nozzles 430 of the dry cleaning tool 420 are indexed across the gas distribution plate 158. In this manner, each gas passage 162 may be addressed and cleaned by the ultrasonic nozzles 430 by repeating operation 710 through operation 730 of the process flow 700 for dry cleaning the gas distribution plate 158 until all the lower density portion 410 of the deposited film 390 is removed from all the gas passages 162. In one example, the system controller 480 aligns the ultrasonic nozzles 430 with a next one or group of gas passages 162 in the gas distribution plate 158 for removing the lower density portion 410 of the deposited film 390 from the gas passages 162 which have yet to be cleaned of the lower density portion 410 of the deposited film 390. At the completion of the dry cleaning procedure, as shown in FIG. 5B, the deposited film 390 depth is reduced by the removal of the lower density portion 410. The dry cleaning procedure removes the lower density portion 410 of the deposited film 390 to reopen the gas passages 162 in the gas distribution plate 158 without removing material of the gas distribution plate 158 and expanding the diameter, or opening, of the gas passages.

The process flow 600 continues at operation 640 by reinstalling the gas distribution plate 158 in the CVD chamber. The gas distribution plate 158 is devoid of the lower density portion 410 of the deposited film 390 as shown in FIG. 5B. The gas distribution plate 158 has only the high density portion 510 of the deposited film 390 adjacent the second side 220 as shown in FIG. 5B.

At operation 650, a second gas is flowed through the plurality of gas passages 162 in the gas distribution plate 158 to deposit a second material on a second substrate in the CVD chamber 100. This operation may be repeated for several batches of substrates where material is deposited by the CVD chamber 1000 in accordance with a recipe to build devices on the substrates. During deposition, the second gas may additionally form residual deposits on the high density portion 510 of the deposited film 390 already present on the gas distribution plate 158 after the dry cleaning operation. The deposited film 39 continues to deposit and build up over the deposition processes.

FIG. 5C illustrates the deposited film 390 on the gas distribution plate 158 after repeating operation 650 for forming a material layer on several batches of substrates in the CVD chamber. The high density portion 510 of the deposited film 390 has a first high density layer 511 and a second high density layer 512. The first high density layer 511 is disposed on the second side 220 of the gas distribution plate 158. The second high density layer 512 is disposed on the first high density layer 511 opposite the second side 220 of the gas distribution plate 158. The low density portion 410 is disposed on the second high density layer 512. The deposited film 390 begins to clog or obstruct the gas passages 162 in the gas distribution plate 158 requiring cleaning. However, the deposited film 39 is thicker now with both the first high density layer 511 and a second high density layer 512 as well as the low density portion 410.

At operation 660, the gas distribution plate 158 is removed from the CVD chamber 100. The gas passages 162 in the gas distribution plate 158 are more obstructed and the high density portion 510 is thicker. As disclosed above, dry cleaning does not remove the high density portion 510 of the deposited film 390. Since the high density portion 510 is thicker now in the gas passages 162, a different clean process is needed to remove the entirety of the deposited film 390 from the gas passages 162 in the gas distribution plate 158. Therefore, a wet chemical clean or other suitable cleaning operation is needed to remove all the deposited film 390 from the gas passages 162.

At operation 670, a chemical clean procedure is performed on the plurality of gas passages 162 in the gas distribution plate 158. The chemical clean operation strips, or eats away, the entirety of the deposited film 390 including the high density portion 510. FIG. 5D illustrates the gas distribution plate 158 with the deposited film 390 removed therefrom after chemical cleaning, i.e., the deposited film 390 is substantially removed from the second side 220 of the gas distribution plate 158. However, the chemical clean operation additionally eats away at the material of the gas distribution plate 158. The result of chemical cleaning the gas distribution plate 158 is the gas passages 162 are free of the deposited film 390. However, as the gas distribution plate 158 has material eaten away by the chemical clean, the gas passages 162 are enlarged by the removal of material from the sidewalls of the gas passages 162. Thus, there is a limit to the number of times the gas distribution plate 158 may be chemically cleaned before the gas passages 162 enlarge out of specification.

At operation 680, the gas distribution plate 158 is reinstalled in the CVD chamber 100. After installation of the gas distribution plate 158, the CVD chamber may begin operations for depositing material layers on substrates. The deposition operation may be repeated for several batches of substrates where material is deposited by the CVD chamber 100 in accordance with a recipe to build devices on the substrates. During deposition, process gases may additionally form new residual deposits on the gas distribution plate 158. The residual deposits may build up over several deposition processes and begin to clog or obstruct the gas passages 162 in the gas distribution plate 158. After the residual deposits begin to obstruct the gas passages 162 sufficiently that operations for depositing material on the substrate takes too long or cannot be performed uniformly, the gas distribution plate is removed for a second dry cleaning operation in accordance with the process flow 700.

It has been found that the gas distribution plate 158 can typically sustain two chemical cleans prior to the gas passages 162 becoming out of specification due to enlargement. Thus, after a second dry clean operation of the gas distribution plate 158, a second chemical clean operation may be performed when the residual material buildup becomes too large. A third dry clean is available for cleaning the gas distribution plate. The chemical clean process can be repeated through 4 to 5 times before the gas distribution plate may reach end of life. The dry cleaning operations extends the time between each chemical clean operation and thus the overall life of the gas distribution plate. Thus, through the use of the dry cleaning process flow, the life span of the gas distribution plate can be greatly expanded. For example, by dry cleaning the gas distribution plate 158, the life cycle of the gas distribution plate 158 may be doubled resulting in significant savings.

While the foregoing is directed to examples of the present disclosure, other and further examples of the disclosure may be devised without departing from the basic scope thereof, and the scope thereof is determined by the claims that follow.

What is claimed is:

1. A method of dry cleaning a gas distribution plate for a plasma processing system, the method comprising:
placing the gas distribution plate in a dry cleaning tool;
directing ultrasonic waves from a nozzle of the dry cleaning tool at a film deposited in gas passages of the gas distribution plate;
removing film particles from a lower density portion of the deposited film from the gas distribution plate by the dry cleaning tool; and
indexing the nozzle of the dry cleaning tool across the gas distribution plate.

2. The method of claim 1 wherein the nozzle of the dry cleaning tool utilizes ultrasonic waves outside a liquid medium to remove the film particles.

3. The method of claim 2 wherein the film particles are removed by a tube surrounding the nozzle, wherein the tube is coupled to a vacuum.

4. The method of claim 2 wherein the dry cleaning tool has 4 or more nozzles which simultaneously clean four or more gas passages of the gas distribution plate.

5. The method of claim 2 wherein the dry cleaning tool has a table for supporting the gas distribution plate and indexed relative to the nozzle by a controller.

6. The method of claim 2 wherein the dry cleaning tool has a table for supporting the gas distribution plate and the nozzle is indexed relative the table by a controller.

7. The method of claim 2 wherein the nozzle is manually indexed relative to the gas distribution plate.

8. A non-transitory computer readable storage medium comprising a program product which, when executed, is configured to perform an operation for cleaning a gas distribution plate for a plasma processing system, the operation comprising:
placing the gas distribution plate in a dry cleaning tool;
directing ultrasonic waves from a nozzle of the dry cleaning tool at a film deposited in gas passages of the gas distribution plate;
removing film particles from a lower density portion of the deposited film from the gas distribution plate by the dry cleaning tool; and
indexing the nozzle of the dry cleaning tool across the gas distribution plate.

9. The non-transitory computer readable storage medium of claim 8 wherein the nozzle of the dry cleaning tool utilizes ultrasonic waves outside a liquid medium to remove the film particles.

10. The non-transitory computer readable storage medium of claim 9, wherein the film particles are removed by a tube surrounding the nozzle, wherein the tube is coupled to a vacuum.

11. The non-transitory computer readable storage medium of claim 9, wherein the dry cleaning tool has 4 or more nozzles which simultaneously clean four or more gas passages of the gas distribution plate.

12. The non-transitory computer readable storage medium of claim 9, wherein the dry cleaning tool has a table for supporting the gas distribution plate and indexed relative to the nozzle by a controller.

13. The non-transitory computer readable storage medium of claim 9, wherein the dry cleaning tool has a table for supporting the gas distribution plate and the nozzle is indexed relative the table by a controller.

14. The non-transitory computer readable storage medium of claim 9, wherein the nozzle is manually indexed relative to the gas distribution plate.

15. An apparatus for cleaning a gas distribution plate for a plasma processing system, comprising:
a processor coupled to at least one non-transitory computer readable medium, wherein the at least one non-transitory computer readable medium includes instructions which when executed by the processor are configured to perform a method for dry cleaning a gas distribution plate of a plasma processing system comprising:
placing the gas distribution plate in a dry cleaning tool;
directing ultrasonic waves from a nozzle of the dry cleaning tool at a film deposited in gas passages of the gas distribution plate;
removing film particles from a lower density portion of the deposited film from the gas distribution plate by the dry cleaning tool; and
indexing the nozzle of the dry cleaning tool across the gas distribution plate.

16. The apparatus of claim 15 wherein the nozzle of the dry cleaning tool utilizes ultrasonic waves outside a liquid medium to remove the film particles.

17. The apparatus of claim 16 wherein the film particles are removed by a tube surrounding the nozzle, wherein the tube is coupled to a vacuum.

18. The apparatus of claim 16 wherein the dry cleaning tool has 4 or more nozzles which simultaneously clean four or more gas passages of the gas distribution plate.

19. The apparatus of claim 16 wherein the dry cleaning tool has a table for supporting the gas distribution plate and indexed relative to the nozzle by a controller.

20. The apparatus of claim 16 wherein the dry cleaning tool has a table for supporting the gas distribution plate and the nozzle is indexed relative the table by a controller.
